(19) United States
(12) Patent Application Publication
(10) Pub. No.: US 2024/0189815 A1
(43) Pub. Date: Jun. 13, 2024

(54) FLUIDIC SENSING ASSEMBLY WITH FLEXIBLE SUBSTRATE

(71) Applicant: ANALOG DEVICES, INC., Wilmington, MA (US)

(72) Inventor: David Frank Bolognia, Charlestown, MA (US)

(21) Appl. No.: 18/531,467

(22) Filed: Dec. 6, 2023

Related U.S. Application Data
(60) Provisional application No. 63/430,952, filed on Dec. 7, 2022.

(51) Int. Cl. B01L 3/00; B81B 7/00

(52) U.S. Cl. CPC B01L 3/502715; B81B 7/0096; B01L 2300/0645; B01L 2300/0663; B01L 2300/123; B01L 2300/1827; B01L 2300/1894; B81B 2201/05; B81B 2207/03; B81B 2207/07

(57) ABSTRACT

A sensor assembly may include an integrated circuit die. A sensor assembly may include an interconnect connected to the integrated circuit die. A sensor assembly may include an interposer mounted over and connected to the interconnect. A sensor assembly may include a heating element disposed in or on the interposer. A sensor assembly may include a sensor configured to transduce a property of one or more sample fluids. A sensor assembly may include a thermal pathway between the sensor and the heating element.

### CROSS-REFERENCE TO RELATED APPLICATIONS

This application claims priority to U.S. Provisional Patent Application No. 63/430,952, filed Dec. 7, 2022, the entire contents of which are incorporated by reference herein in their entirety and for all purposes.

### BACKGROUND

The present application relates to a sensor assembly used for fluidic sensing. Sensing a fluid to obtain information about the fluid is desirable in many circumstances. Sensing of biological fluids, such as blood, for various constituent materials of the biological fluids is often performed in a medical setting. A sensor assembly can be better designed for fluidic sensing to more conveniently and economically sense fluids.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one embodiments, the techniques described herein relate to a sensor assembly. The sensor assembly can comprise an integrated circuit die. The sensor assembly can comprise an interconnect connected to the integrated circuit die. The sensor assembly can comprise an interposer mounted over and connected to the interconnect. The sensor assembly can comprise a sensor configured to transduce a property of one or more sample fluids, a thermal pathway between the sensor and the integrated circuit die, the thermal pathway extending through the interposer and the interconnect.

In some embodiments, the sensor assembly can further include a heating element configured to heat the one or more sample fluids. In some embodiments, the sensor assembly can further include a thermal layer mounted to the interposer, wherein the sensor is disposed on the thermal layer. In some embodiments, the sensor assembly can further include a resist layer mounted to the interposer, wherein the sensor is disposed on the resist layer. In some embodiments, the resist layer electronically isolates the sensor and the interposer in use of the sensor assembly. In some embodiments, the resist layer is thermally conductive. In embodiments, the resist layer is a photoresist layer. In some embodiments, wherein the heating element is disposed between the interconnects and the integrated circuit die. In some embodiments, the heating element is disposed between the resist layer and the integrated circuit die. In some embodiments, the heating element is disposed in or on the interposer. In some embodiments, the heating element is disposed in or on the integrated circuit die. In some embodiments, the integrated circuit die does not contact a liquid during use of the sensor assembly. In some embodiments, the integrated circuit die includes silicon. In some embodiments, the integrated circuit die includes one or more amplifiers. In some embodiments, the integrated circuit die includes one or more converters. In some embodiments, the interconnect includes a plurality of copper pillars. In some embodiments, the interconnect is thermally conductive. In some embodiments, the interposer is electrically connected to the integrated circuit die through the interconnect. In some embodiments, the interposer is electrically connected to the integrated circuit die. In some embodiments, the interposer includes a via connected to the interconnect and a trace connected to the heating element. In some embodiments, the heating element includes a resistive heater. In some embodiments, the heating element includes a serpentine pattern. In some embodiments, the heating element has a resistance in a range of 80-120 ohm. In some embodiments, the thermal layer conducts heat between the sensor and the heating element in use of the sensor assembly. In some embodiments, the thermal layer electronically isolates the sensor and the interposer in use of the sensor assembly. In some embodiments, the thermal layer includes polyimide. In some embodiments, the thermal layer includes silicon nitride. In some embodiments, the sensor is electronically isolated from the interposer. In some embodiments, the sensor includes a gold pad. In some embodiments, the sensor includes a functionalized pad. In some embodiments, the sensor assembly can further include a plurality of electrodes disposed on the interposer over a plurality of vias through the interposer. In some embodiments, the sensor assembly can further include a plurality of electrodes disposed on the resist layer. In some embodiments, each of one or more of the plurality of electrodes on the interposer is disposed along an edge of the interposer. In some embodiments, the sensor assembly can further include an underfill layer positioned between the interposer and the integrated circuit die, and around the interconnect. In some embodiments, the sensor assembly can further include an electrical passivation layer disposed on at least the heating element to electrically passivate a local area. In some embodiments, the sensor assembly can further include one or more heater control pads disposed in or on the integrated circuit die, the one or more heater control pads configured to provide power to the heating element. In some embodiments, the sensor assembly can further include one or more electrode control pads disposed in or on the integrated circuit die, the one or more electrode control pads electrically connected to the plurality of electrodes on the resist layer. In some embodiments, the sensor is exposed to a fluid pathway through which the one or more sample fluids is to be delivered. In some embodiments, the sensor assembly can further include a plurality of integrated circuit dies, a plurality of interconnects attached to the plurality of integrated circuit die, a plurality of interposers mounted to the plurality of interconnects, a plurality of sensors configured to transduce a property of one or more sample fluids, and a plurality of heating elements configured to heat the one or more sample fluids through a corresponding plurality of interposers. In some embodiments, the sensor assembly can further include a stiffener to provide support to the sensor assembly. In some embodiments, the sensor assembly can further include a flow cell coupled to the plurality of integrated circuit dies and forming a fluid pathway on a first side of the plurality of integrated circuit dies. In some embodiments, the sensor assembly can further include a cooling block coupled to a second side of the plurality of integrated circuit dies, opposite to the first side of the plurality of integrated circuit dies, the cooling block configured to cool the sensor assembly in use. In embodiments, the cooling block is coupled to the plurality of integrated circuit dies through a thermally conductive adhesive. In some embodiments, the sensor assembly can further include a connector configured to electrically connect the plurality of integrated circuit dies to one or more external devices.

In another embodiments, the techniques described herein relate to a sensor assembly. The sensor assembly can comprise an integrated circuit die. The sensor assembly can comprise an interconnect connected to the integrated circuit die. The sensor assembly can comprise an interposer mounted over and connected to the interconnect. The sensor assembly can comprise a sensor configured to transduce a property of one or more sample fluids. The sensor assembly can comprise a heating element configured to heat the one or more sample fluids. The sensor assembly can comprise thermal pathway between the sensor and the heating element.

In some embodiments, the heating element is disposed in or on the interposer. In some embodiments, the heating element is disposed in or on the integrated circuit die.

In another embodiment, the techniques described herein relate to a sensor assembly. The sensor assembly can comprise an integrated circuit die. The sensor assembly can comprise an interconnect connected to the integrated circuit die. The sensor assembly can comprise an interposer mounted over and connected to the interconnect. The sensor assembly can comprise a heating element disposed in or on the interposer. The sensor assembly can comprise a sensor configured to transduce a property of one or more sample fluids. The sensor assembly can comprise a thermal pathway between the sensor and the heating element.

In some embodiments, the sensor assembly can include a resist layer mounted to the interposer, wherein the sensor is disposed on the resist layer. In some embodiments, the sensor assembly can include an electrical passivation layer disposed on the heating element.

In another embodiment, the techniques described herein relate to a sensor assembly. The sensor assembly can comprise an integrated circuit die forming a thermal platform. The sensor assembly can comprise one or more interconnects connected to the integrated circuit die. The sensor assembly can comprise an interposer mounted over and connected to the one or more interconnects. The sensor assembly can comprise a resist layer mounted over and connected to the interposer. The sensor assembly can comprise a reaction site disposed in or on the resist layer, the reaction site configured to transduce a property of one or more sample fluids. The sensor assembly can comprise a heating element disposed on the integrated circuit die, the heating element configured to heat the one or more sample fluids, wherein the interposer and at least one of the one or more interconnects form a thermal pathway between the reaction site and the heating element.

In some embodiments, the resist layer includes a thermal conductive layer including at least one of a polyimide or silicon nitride. In some embodiments, the resist layer includes photoresist. In some embodiments, the resist layer electrically isolates the reaction site and the interposer. In some embodiments, the integrated circuit die includes one or more amplifiers and one or more converters. In some embodiments the sensor assembly can further include a plurality of electrodes disposed on the interposer over a plurality of vias through the interpose, wherein the plurality of electrodes are coupled to at least one interconnect of the one or more interconnects, and wherein each of the plurality of electrodes are configured to transmit electrical signals received from the integrated circuit die through the at least one interconnect. In some embodiments the sensor assembly can further include one or more electrode control pads disposed in or on the integrated circuit die, the one or more electrode control pads electrically connected to the plurality of electrodes on the resist layer. In some embodiments the sensor assembly can further include an underfill layer positioned between the interposer and the integrated circuit die, the underfill layer filling a space around the one or more interconnects. In some embodiments the sensor assembly can further include an electrical passivation layer disposed on at least the heating element to electrically passivate a localized area. In some embodiments the sensor assembly can further include one or more heater control pads disposed in or on the integrated circuit die, the one or more heater control pads configured to provide power to the heating element. In some embodiments, the reaction site is exposed to a fluid pathway through which the one or more sample fluids is to be delivered.

In another embodiment, the techniques described herein relate to a fluidic sensor package. The fluidic sensor package can comprise a plurality of sensor assemblies, each sensor assembly of the plurality of sensor assemblies comprising: an integrated circuit die forming a thermal platform; one or more interconnects connected to the integrated circuit die; an interposer mounted connected to the one or more interconnects; a reaction site disposed on the interposer, the reaction site configured to transduce a property of one or more sample fluids; and a heating element disposed on the integrated circuit die, the heating element configured to heat the one or more sample fluids. The fluidic sensor package can comprise a flow cell coupled to the plurality of sensor assemblies and forming a fluid pathway for the one or more sample fluids on a first side of the plurality of sensor assemblies.

In some embodiments, the fluidic sensor package can further include a stiffener to provide support to the plurality of sensor assemblies. In some embodiments, the fluidic sensor package can further include a cooling block coupled to a second side of the plurality of sensor assemblies, opposite to the first side of the plurality of sensor assemblies, the cooling block configured to disperse heat from the plurality of sensor assemblies. In some embodiments, the cooling block is coupled to the plurality of sensor assemblies through a thermally conductive adhesive. In some embodiments, the fluidic sensor package can further include a connector configured to electrically connect the plurality of sensor assemblies to one or more external devices. In some embodiments, each sensor assembly of the plurality of sensor assemblies further comprises: a plurality of electrodes disposed on the interposer over a plurality of vias through the interposer, the plurality of electrodes coupled to at least one interconnect of the one or more interconnects, and at least a portion of the plurality of electrodes electrically coupled to at least a portion of the plurality of electrodes of another sensor assembly of the plurality of sensor assemblies and transmit electrical signals received from the integrated circuit die through the at least one interconnect. In some embodiments, each sensor assembly of the plurality of sensor assemblies further includes: one or more electrode control pads disposed in or on the integrated circuit die, the one or more electrode control pads electrically connected to the plurality of electrodes on the resist layer.

In another embodiment, the techniques described herein relate to an electronic assembly. The electronic assembly can comprise a sensor assembly comprising: a first integrated circuit die forming at least a first portion of a thermal platform; a first one or more interconnects connected to the first integrated circuit die; an interposer mounted over and connected to the first one or more interconnects; a reaction site disposed in or on the interposer, the reaction site configured to transduce a property of one or more sample fluids; and a heating element disposed on the first integrated circuit die, the heating element configured to heat the one or more sample fluids. The electronic assembly can comprise one or more electrical connections configured to receive control signals from an external device, the one or more electrical connections comprising: one or more electrical traces electrically coupled to the external device; a second integrated circuit die forming at least a second portion of the thermal platform; and a second one or more interconnects connected to the second integrated circuit die.

In some embodiments, the sensor assembly and the one or more electrical connections are electrically and physically connected via the thermal platform.

In another embodiment, the techniques described herein relate to a sensor assembly. The sensor assembly can comprise an integrated circuit. The sensor assembly can comprise one or more interconnects coupled to the integrated circuit. The sensor assembly can comprise a substrate mounted over and connected to the one or more interconnects, the substrate comprising: an interposer; a heating element disposed on the interposer; a photoresist layer mounted over and connected to the interposer; and a reaction pad disposed on the interposer above the heating element, the reaction pad configured to transduce a property of one or more sample fluids; wherein the heating element is configured to heat the one or more sample fluids.

In some embodiments, the sensor assembly can further include an electrical passivation layer disposed on the heating element, wherein the electrical passivation layer electrically isolates the reaction pad and the heating element. In some embodiments, the photoresist layer and the electrical passivation layer are thermally conductive, and the electrical passivation layer includes at least one of a polyimide or silicon nitride. In some embodiments, the photoresist layer and electrical passivation layer form a thermal pathway between the reaction pad and the heating element. In some embodiments, the integrated circuit includes one or more amplifiers and one or more converters. In some embodiments, the substrate is comprised of flexible material and the substrate further comprises: a plurality of electrodes disposed in the photoresist layer and electrically connected to a plurality of electrical connections disposed on the interposer over a plurality of vias through the interposer, the plurality of electrodes are electrically coupled to at least one interconnect of the one or more interconnects via the plurality of electrical connections, and each of the plurality of electrodes are configured to transmit electrical signals received from the integrated circuit through the at least one interconnect. In some embodiments, the substrate further includes an underfill layer coupled on one side of the interposer in contact with the integrated circuit, the underfill layer configured to receive the one or more interconnects. In some embodiments, the substrate further includes one or more heater control circuits disposed in or on the integrated circuit, the one or more heater control circuits configured to provide power to the heating element and to convert heat flow from the reaction pad into one or more electrical signals. In some embodiments, the reaction pad is exposed to a fluid pathway through which the one or more sample fluids is to be delivered.

In another embodiment, the techniques described herein relate to a fluidic sensor package. The fluidic sensor package can comprise a plurality of sensor assemblies, each sensor assembly of the plurality of sensor assemblies comprising: an integrated circuit; one or more interconnects coupled to the integrated circuit; and a substrate mounted over and connected to the one or more interconnects, the substrate including: a heating element configured to heat one or more sample fluids; a photoresist layer mounted over the heating element; and a reaction pad disposed on the photoresist layer above the heating element, the reaction pad configured to transduce a property of the one or more sample fluids. The fluidic sensor package can comprise a flow cell coupled to the plurality of sensor assemblies and forming a fluid pathway for the one or more sample fluids on a first side of the plurality of sensor assemblies.

In some embodiments, the fluidic sensor package can further include a stiffener to provide support to the plurality of sensor assemblies. In some embodiments, the fluidic sensor package can further include a cooling block coupled to a second side of the plurality of sensor assemblies, opposite to the first side of the plurality of sensor assemblies, the cooling block configured to disperse heat from the plurality of sensor assemblies. In some embodiments, the cooling block is coupled to the plurality of sensor assemblies through a thermally conductive adhesive. In some embodiments, the fluidic sensor package can further include a connector configured to electrically connect the plurality of sensor assemblies to one or more external devices.

In some embodiments, each sensor assembly of the plurality of sensor assemblies further comprises: a plurality of electrodes disposed in the photoresist layer and electrically connected to a plurality of electrical connections. In these embodiments, the plurality of electrodes can be electrically coupled to at least one interconnect of the one or more interconnects via the plurality of electrical connections. In these embodiments, each of the plurality of electrodes can be configured to transmit electrical signals received from the integrated circuit through the at least one interconnect. In these embodiments, at least a portion of the plurality of electrodes can be electrically coupled to at least a portion of the plurality of electrodes of another sensor assembly of the plurality of sensor assemblies and transmit electrical signals received from the integrated circuit through the at least one interconnect. In some embodiments, the fluidic sensor package can further include a connector configured to electrically connect the plurality of sensor assemblies to one or more external devices.

In another embodiment, the techniques described herein relate to an electronic assembly. The electronic assembly can comprise a sensor assembly comprising: a first integrated circuit; a first one or more interconnects coupled to the first integrated circuit; and a substrate mounted over and connected to the first one or more interconnects, the substrate including: an interposer; a heating element disposed on the interposer configured to heat one or more sample fluids; and a reaction pad disposed on the interposer above the heating element, the reaction pad configured to transduce a property of the one or more sample fluids. The electronic assembly can comprise one or more electrical connections configured to receive control signals from an external device, the one or more electrical connections comprising: one or more electrical traces electrically coupled to the external device; a second integrated circuit; and a second one or more interconnects connected to the second integrated circuit.

In some embodiments, the first integrated circuit and the second integrated circuit are electrically and physically coupled. In some embodiments, the substrate further includes an electrical passivation layer disposed on the heating element, wherein the electrical passivation layer electrically isolates the reaction pad and the heating element. In some embodiments, the substrate further includes a photoresist layer; and wherein the photoresist layer and the electrical passivation layer are thermally conductive. In some embodiments, the substrate further comprises: a plurality of electrodes disposed in the photoresist layer; and wherein the plurality of electrodes are electrically coupled to at least one interconnect of the first one or more interconnects, each of the plurality of electrodes are configured to transmit electrical signals received from the first integrated circuit through the at least one interconnect.

### BRIEF DESCRIPTION OF THE DRAWINGS

Various implementations will be described hereinafter with reference to the accompanying drawings. These implementations are illustrated and described by example only and are not intended to limit the scope of the disclosure. In the drawings, similar elements have similar reference numerals.

FIG. 1A illustrates an exploded view of a sensor assembly, according to an embodiment.

FIG. 1B illustrates an assembled sensor assembly, according to an embodiment.

FIGS. 1C-1E schematically illustrate a sensor assembly and electrical connections that can provide input/output connections for the sensor assembly, according to an embodiment.

FIG. 2A illustrates an exploded view of another sensor assembly, according to an embodiment.

FIG. 2B illustrates the assembled sensor assembly, according to an embodiment.

FIGS. 2C-2E schematically illustrate the sensor assembly and electrical connections that can provide input/output connections for the sensor assembly, according to an embodiment.

FIG. 3A illustrates an exploded view of another sensor assembly, according to an embodiment.

FIG. 3B illustrates the assembled sensor assembly, according to an embodiment.

FIGS. 3C-3E schematically illustrate the sensor assembly and electrical connections that can provide input/output connections for the sensor assembly, according to an embodiment.

FIG. 4A illustrates an exploded view of another sensor assembly, according to an embodiment.

FIG. 4B illustrates the assembled sensor assembly, according to an embodiment.

FIGS. 4C-4E schematically illustrate the sensor assembly and electrical connections that can provide input/output connections for the sensor assembly, according to an embodiment.

FIG. 5A is an exploded view of a sensor assembly, according to an embodiment.

FIG. 5B illustrates a cross section of the sensor assembly, according to an embodiment.

FIG. 5C illustrates a top view of the sensor assembly with a transparent thermal layer, according to an embodiment.

FIG. 5D illustrates an exploded view of the sensor assembly with a transparent interposer, according to an embodiment.

FIG. 6 illustrates another embodiment of a sensor assembly according to this disclosure.

FIGS. 7A-7D illustrate an embodiment of a fluidic sensor package that utilizes a plurality of sensor assemblies.

### DETAILED DESCRIPTION

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of embodiments.

Generally described, one or more aspects of the present disclosure relate to a sensor assembly used for fluidic sensing. In certain embodiments, this disclosure relates to a sensor assembly having an interposer for fluidic sensing that can isolate a die from sample fluids. Conventional integrated circuits for sensing fluids have integrated circuit dies exposed to the liquids, and are therefore specially packaged with wires and conductors separated from the liquids. In various embodiments disclosed herein, an interposer can be used to separate an integrated circuit die from the liquids to improve packaging and to make manufacturing of integrated circuits used for fluidic sensing easier.

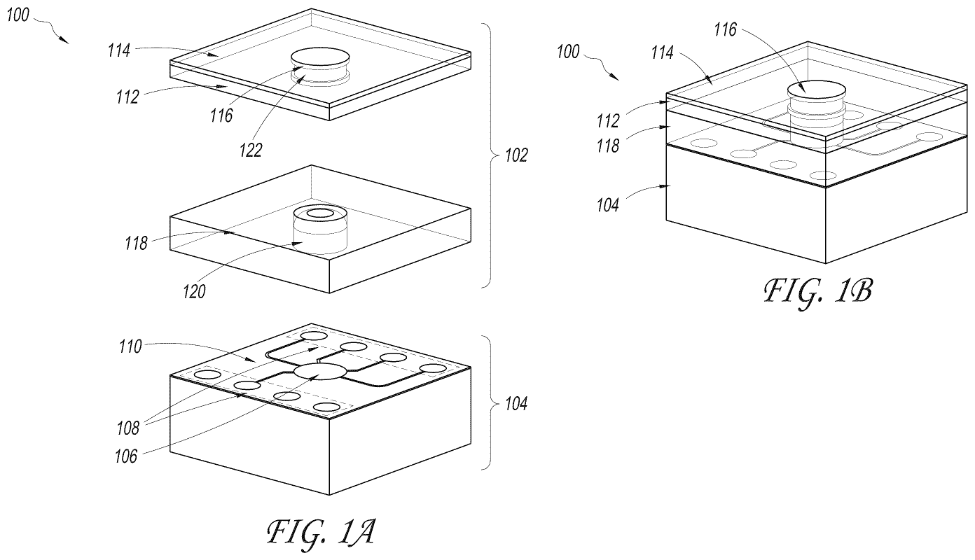

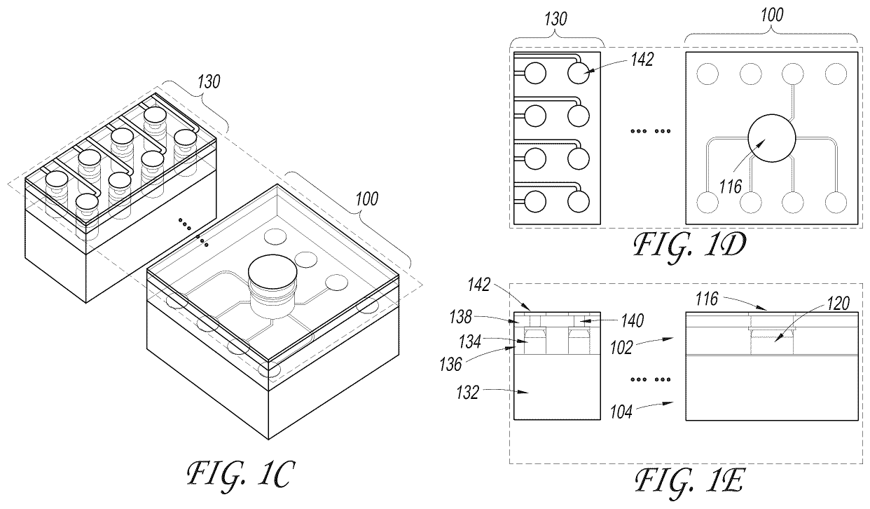

FIGS. 1A-1E illustrate an embodiment of a sensor assembly 100 according to this disclosure. FIG. 1A is an exploded view of the sensor assembly 100. FIG. 1B illustrates the assembled sensor assembly 100, and FIGS. 1C-1E schematically show the assembled sensor assembly 100 in an electronic assembly with electrical connections 130 that can provide input/output connections for the sensor assembly 100. As illustrated in FIGS. 1A and 1B, the sensor assembly 100 can include a thermal interposer 102 and a thermal platform 104. In some embodiments, the thermal platform 104 can be a monolithic chip. In some embodiments, the thermal platform 104 can include and/or be formed from an integrated circuit chip or die. In some embodiments, the thermal platform 104 can include a heating element 106 (also referred to as a heater) and a plurality of heater control pads 108 (also referred to as control electrodes) connected to the heating element 106. The heating element 106 can be resistive. The heating element 106 can be formed of any suitable materials, for example, nickel phosphorus (“NiP”), ruthenium (“Ru”), etc. In some embodiments, the heating element 106 can be positioned in a central area of the thermal platform 104, proximate a top side of the thermal platform 104. In some embodiments, the thermal platform 104 can further include an electrical passivation layer 110 disposed on the top side of the thermal platform 104. The electrical passivation layer 110 can electrically passivate the local area. In some embodiments, the electrical passivation layer 110 can electrically isolate the heating element 106 and/or the heater control pads 108 on the thermal platform 104 from other components (e.g., interconnects 120 in the thermal interposer 102). The electrical passivation layer 110 can be formed of a material that is electrically insulating to electrically passivate. In some embodiments, the electrical passivation layer 110 can be formed of a material that has a high thermal conductivity so as to convey heat from the heating element 106. In some embodiments, the electrical passivation layer 110 can be formed of, for example, silicon nitride (“Si3N4”), polyimide, etc.

In accordance with various embodiments disclosed herein, the thermal interposer 102 can be disposed on top of the thermal platform 104. In some embodiments, the thermal interposer 102 can include a fluidic interposer 112 (also referred to as a substrate) configured to separate a sample to be sensed on top of the sensor assembly 100 from other components of the sensor assembly 100. The thermal interposer 102 can further include a resist layer 114 disposed on the fluidic interposer 112. In some embodiments, a reaction site 116 can be disposed on the thermal interposer 102. The reaction site 116 may be disposed on the resist layer 114 or directly on the fluidic interposer 112. In some embodiments, the resist layer 114 can be a biocompatible and/or photoresist layer and may further define surface properties, geometric patterns, and other mechanical or biochemical properties to the sensor assembly 100.

The thermal interposer 102 can further include an underfill 118 disposed between the fluidic interposer 112 and the thermal platform 104. One or more interconnects 120 may be embedded in the underfill 118 and configured to thermally connect the thermal platform 104 and the thermal interposer 102. In some embodiments, the interconnects 120 may be copper pillars having a copper body and solder cap. In some embodiments, the thermal interposer 102 can further include one or more conductive vias 122 disposed in the fluidic interposer 112, thermally connecting the reaction site 116 to a bottom side of the fluidic interposer 112. When the heating element 106 is connected to electrical power, heat can be generated and transmitted from the heating element 106 through the electrical passivation layer 110, the interconnects 120 and vias 122 to the reaction site 116. The reaction site 116 may be electrically isolated from the heating element 106. As shown in FIGS. 1A and 1B, the heating element 106, the interconnects 120, the via 122, and the reaction site 116 may have comparable diameters to enable efficient heat transfer between the components.

In some embodiments, the sensor assembly 100 can be connected to a set of electrical connections 130 through the thermal platform 104 as shown in FIGS. 1C-1E. The electrical connections 130 can similarly include a thermal platform 132 having an integrated circuit, for example, a complementary metal-oxide-semiconductor application-specific integrated circuit (“CMOS ASIC”). In some embodiments, thermal platform 132 of the electrical connections 130 and thermal platform 104 of the sensor assembly 100 can be connected or form a single body. In some embodiments, the electrical connections 130 can further include interconnects 134 (e.g., copper pillars) embedded in an underfill 136 on top of the thermal platform 132. In some embodiments, the electrical connections 130 can further include a flexible circuit substrate 138 with vias 140 and traces 142 on top of the interconnects 134.

In some embodiments, the electrical connections 130 can further be connected to an external device, such as a package substrate (e.g., PCB) or another device (e.g., another die) by way of any suitable electrical connector, such as wire bonds, to the traces 142. For example, the traces 142 may be electrically coupled to an external device such that the traces 142 can receive input signals for the electrical connections 130 and transmit output signals to the external device.

In some embodiments, control signals can be sent, for example, from an external device, to electrical connections 130 and then conveyed through the thermal platform 132 and/or thermal platform 104 and through the heater control pads 108 to the heating element 106 and/or the reaction site 116 on the resist layer 114. In some embodiments, an electrical current can be transmitted through the sensor assembly 100 to the heating element 106 to generate heat, and the heating element 106 can pass the heat through the electrical passivation layer 110, the interconnect 120, the fluidic interposer 112, the resist layer 114, and/or the reaction site 116 to at least a portion of the sample fluids around the reaction site 116. In some embodiments, the heating element 106 can pass the heat through only the resist layer 114 and the reaction site 116 to the at least a portion of the sample fluids. The generated heat can heat the portion of sample fluids such that the portion of sample fluids chemically, mechanically, or biologically reacts to achieve a desirable sensing condition. The integrated circuit die can then be configured to turn off the current to the heating element 106 and stop generating heat at the heating element 106. When the heating element 106 stops providing heat to the reaction site 116, the reaction site 116 can be configured to transduce and transfer temperature information (e.g. a change in temperature) to the thermal platform 104 through the fluidic interposer 112 and the one or more interconnects 120.

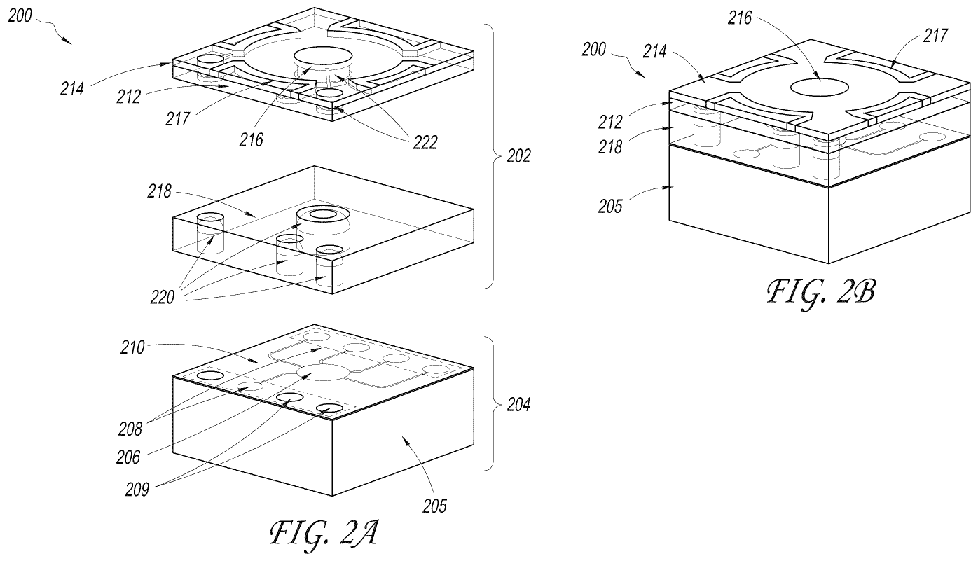

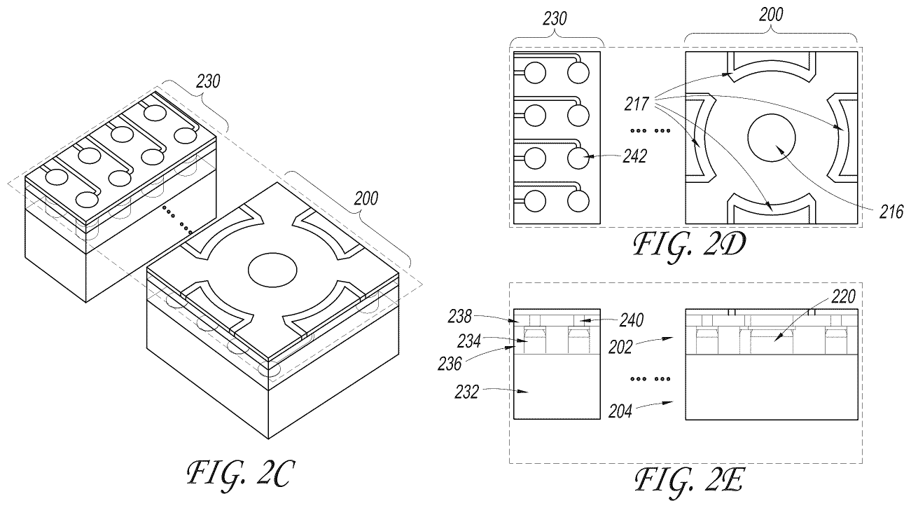

FIGS. 2A-2E show another embodiment of a sensor assembly 200 according to this disclosure. FIG. 2A is an exploded view of the sensor assembly 200. FIG. 2B shows the assembled sensor assembly 200, and FIGS. 2C-2E schematically show the assembled sensor assembly 200 in an electronic assembly with electrical connections 230 that can provide input/output connections for the sensor assembly 200. Similar to the sensor assembly 100 of FIGS. 1A-1E, the sensor assembly 200 can include a thermal platform 204 and a thermal interposer 202, but with additional electrodes 217 disposed on the thermal interposer 202 as shown in FIG. 2A. The thermal platform 204 can include a monolithic chip 205 and an electrical passivation layer 210 disposed on the chip. The electrical passivation layer 210 can be, for example, a thin Si3N4 layer, or other suitable material. In some embodiments, a heating element 206 can be disposed beneath the electrical passivation layer 210. The heating element 206 can be resistive. In some embodiments, the thermal platform 204 can include a plurality of electrodes, such as heater control pads 208 and electrode control pads 209. In some embodiments, the heater control pads 208 can be configured to control the heating element 206 and disposed beneath the electrical passivation layer 210. In some embodiments, the electrode control pads 209 configured to control electrodes 217 on top of the thermal interposer 202 and may not be covered by the electrical passivation layers 210.

The thermal interposer 202 can similarly include a fluidic interposer 212 and a resist layer 214 on top of the fluidic interposer 212. One or more reaction sites 216 or electrodes 217 can be disposed on top of the thermal interposer 202, electrically or thermally connected to the thermal platform 204 through vias 222 or traces in the fluidic interposer 212. In some embodiments, the thermal interposer 202 can further include an underfill 218 with one or more interconnects 220 (e.g., copper pillars) configured to electrically or thermally connect the one or more reaction sites 216 and/or electrodes 217 on top of the thermal interposer 202 to the heater control pads 208 and/or electrode control pads 209 in the thermal platform 204. For example, as shown in FIG. 2A, the sensor assembly 200 can include a central reaction site and four electrodes 217. In some embodiments, the central reaction site can be configured to be thermally connected with the heating element 206 underneath the electrical passivation layer 210 as described above. In some embodiments, the electrodes 217 may be electrically connected to the electrode control pads 209 disposed on the thermal platform 204. In some embodiments, the electrical connection between the electrodes 217 and the thermal platform 204 may be enabled by selectively exposing the one or more of the electrode control pads 209 through the passivation layer such that the one or more of the electrode control pads 209 are not electrically insulated from the components above. Electrical connection between the one or more reaction sites 216 or electrodes 217 and the thermal platform 204 can enable information transmission between the two.

In certain embodiments, each of the electrodes 217 may be positioned along an edge of the thermal interposer 202 such that another sensor assembly 200 according to this disclosure may be positioned next to the current one and be electrically connected through a set of electrical leads on electrodes 217 exposed on the edges of the thermal interposers 202. In certain embodiments, electrodes 217 have an approximate “M” shape, as illustrated in FIGS. 2A-2E, with the set of electrical leads positioned on the edge of the thermal interposer 202. When more than one sensor assembly 200 is connected along the edges through the electrodes 217, not all of the electrodes 217 on any individual sensor assembly 200 require a connection to the electrode control pads 209 on the thermal platform 204. For example, only two neighboring electrodes 217 are electrically connected to the electrode control pads 209 on the thermal platform 204 in the configuration shown in FIG. 2A. In some embodiments, a third electrode control pad 209, as illustrated in FIG. 2A, can also be electrically connected to the central reaction site 216.

In some embodiments, the sensor assembly 200 can be connected to a set of electrical connections 230 through the thermal platform 204 as shown in FIGS. 2C-2E. The electrical connections 230 can similarly include a thermal platform 232 having an integrated circuit, for example, a complementary metal-oxide-semiconductor application-specific integrated circuit (“CMOS ASIC”). In some embodiments, thermal platform 232 of the electrical connections 230 and thermal platform 204 of the sensor assembly 200 can be connected or form a single body. In some embodiments, the electrical connections 230 can further include interconnects 234 (e.g., copper pillars) embedded in an underfill 236 on top of the thermal platform 232. In some embodiments, the electrical connections 230 can further include a flexible circuit 238 with vias 240 and traces 242 on top of the interconnects 234.

In some embodiments, the electrical connections 230 can further be connected to an external device, such as a package substrate (e.g., PCB) or another device (e.g., another die) by way of any suitable electrical connector, such as wire bonds, to the traces 242. For example, the traces 242 may be electrically coupled to an external device such that the traces 242 can receive input signals for the electrical connections 230 and transmit output signals to the external device.

In some embodiments, control signals can be sent, for example, from an external device, to electrical connections 230 and then conveyed through the thermal platform 232 and/or thermal platform 204 and through the heater control pads 208 to the heating element 206 and/or the reaction site 216 on the resist layer 214. In some embodiments, control signals can be sent, for example, from an external device, to electrical connections 230 and then conveyed through the thermal platform 232 and/or thermal platform 204 and through the electrode control pads 209 to the electrodes 217 and into another sensor assembly 200. Similarly, in some embodiments, control signals can be received by the sensor assembly 200 through the electrodes 217, through the electrode control pads 209, through the heater control pads 208 to the thermal platform 204 and/or the reaction sited 216 in the resist layer. As such, a control signal for the sensor assembly 200 may be received from an external device directly, or through an adjacent sensor assembly 200.

In some embodiments, an electrical current can be transmitted through the sensor assembly 200 to the heating element 206 to generate heat, and the heating element 206 can pass the heat through the electrical passivation layer 210, the interconnect 220, the fluidic interposer 212, the resist layer 214, and/or the reaction site 216 to at least a portion of the sample fluids around the reaction site 216. In some embodiments, the heating element 106 can pass the heat through only the resist layer 214 and the reaction site 216 to the at least a portion of the sample fluids. The generated heat can heat the portion of sample fluids such that the portion of sample fluids chemically, mechanically, or biologically reacts to achieve a desirable sensing condition. The integrated circuit die can then be configured to turn off the current to the heating element 206 and stop generating heat at the heating element 206. When the heating element 206 stops providing heat to the reaction site 216, the reaction site 216 can be configured to transduce and transfer temperature information (e.g. a change in temperature) to the thermal platform 204 through the fluidic interposer 212 and the one or more interconnects 220.

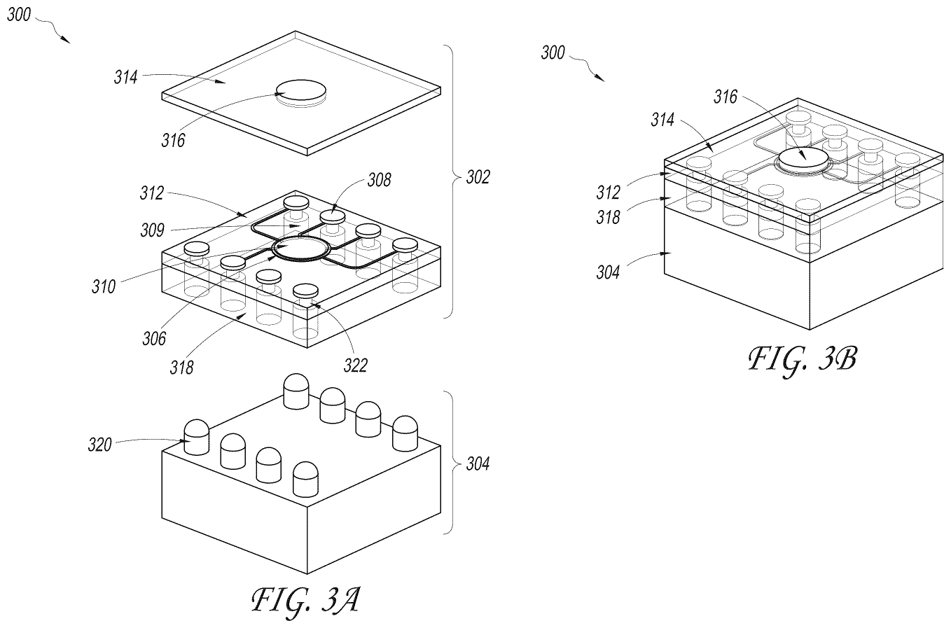

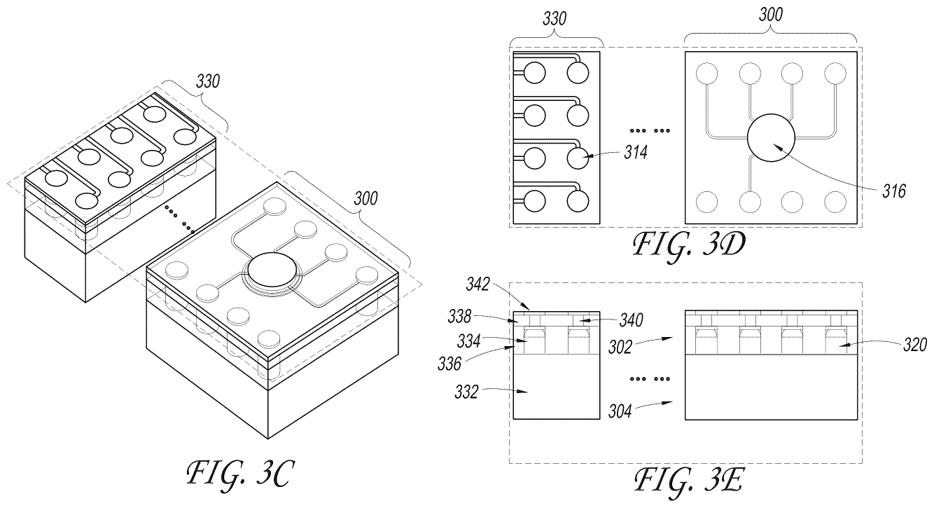

FIGS. 3A-3E show another embodiment of a sensor assembly 300 according to this disclosure. FIG. 3A is an exploded view of the sensor assembly 300. FIG. 3B shows the assembled sensor assembly 300 and FIGS. 3C-3E schematically show the assembled sensor assembly 300 in an electronic assembly with electrical connections 330 that can provide input/output connections for the sensor assembly 300. In some embodiments, the sensor assembly 300 can include an integrated circuit 304 (e.g., CMOS ASIC). In some embodiments, the integrated circuit 304 can be a monolithic chip. The integrated circuit 304 can include a plurality of electrical connection sites (e.g., aluminum pads) disposed on a top side of the integrated circuit 304. The integrated circuit 304 can further include interconnects 320 (e.g., copper pillars) disposed on the plurality of electrical connection sites.

In certain embodiments, the sensor assembly 300 can further include a flexible circuit 302 (e.g., active flex) disposed on top of the integrated circuit 304. The flexible circuit 302 can include a fluidic interposer 312 (e.g., a flexible substrate). The fluidic interposer 312 can include one or more heating elements 306 and associated electrical connections 308 coupled to the fluidic interposer 312. For example, as shown in FIG. 3A, the fluidic interposer 312 can include one resistive heating element 306 (e.g., Ru, Ni, etc.) sputtered or plated on the fluidic interposer 312. In some embodiments, one or more of the electrical connections 308 can include electrodes on surfaces of the fluidic interposer 312 and vias/traces 322 through the fluidic interposer 312. One or more of the electrical connections 308 can be connected to the heating element 306 to provide power and generate heat.

The electrical connections 308 can electrically and/or thermally connect to the interconnects 320 on the integrated circuit 304. In some embodiments, the flexible circuit 302 can further include a bottom side resist layer 318 (e.g., underfill) coupled to a bottom side of the fluidic interposer 312 and configured to receive the interconnects 320 on the integrated circuit 304, ensuring stable connection between the interconnects 320 on the integrated circuit 304 and the electrical connections 308 on the fluidic interposer 312.

In accordance with various embodiments disclosure herein, an electrical passivation layer 310 (e.g., Si3N4) can be disposed at least on top of the heating element 306 to coat at least a top side of the heating element 306 and thereby electrically passivate the local area, whereas one or more of the one or more of the electrical connections 308 on the fluidic interposer 312 are exposed through the passivation layer 310. A reaction pad 316 (e.g., gold pad) with a proper thickness can be sputtered on the electrical passivation layer 310. In some embodiments, the reaction pad 316 and the rest of the sensor assembly 300 can be thermally connected to the heating element 306 and electrically isolated by the passivation layer 310. The thickness of the reaction pad 316 can be further defined by electroplating process. In some embodiments, a photoresist layer 314 (e.g., biocompatible resist layer) can be added on top of the fluidic interposer 312 to further define the surface properties, geometric patterns, and other mechanical or biochemical properties of the sensor assembly 300. The reaction pad 316 can be embedded in the photoresist layer 314 with top and bottom sides exposed.

In accordance with various embodiments, heat can flow both ways between the reaction pad 316 and the heating element 306. In some embodiments, heat can flow between the reaction pad 316 and the heating element 306 through at least the electrical passivation layer 310. The heating element 306 can include a control circuit 309 to convert the heat flow from the reaction pad 316 to one or more electrical signals (e.g., temperature signals). In some embodiments, signals can be sent through the interconnects 320 to the heating element 306 to generate heat which is transferred upward to the reaction pad 316. In such embodiment, heat intentionally does not flow down through the interconnects 320. In some embodiments, electrical signals from the control circuit 309 in the heating element 306 can be transmitted down to the integrated circuit 304 through the one or more electrical connections 308 on the fluidic interposer 312 and the interconnects 320. Examples of control circuits 309 which can be included int the heating element 306 may be found in U.S. Patent Publication No. US20220126300, the entire contents of which are incorporated by reference herein in their entirety and for all purposes.

In some embodiments, the sensor assembly 300 can be connected to a set of electrical connections 330 through the integrated circuit 304 as shown in FIGS. 3C-3E. The electrical connections 330 can similarly include a thermal platform 332 having an integrated circuit, for example, a complementary metal-oxide-semiconductor application-specific integrated circuit (“CMOS ASIC”). In some embodiments, thermal platform 332 of the electrical connections 330 and integrated circuit 304 of the sensor assembly 300 can be connected or form a single body. In some embodiments, the electrical connections 330 can further include interconnects 334 (e.g., copper pillars) embedded in an underfill 336 on top of the thermal platform 332. In some embodiments, the electrical connections 330 can further include a flexible circuit 338 with vias 340 and traces 342 on top of the interconnects 334.

In some embodiments, the electrical connections 330 can further be connected to an external device, such as a package substrate (e.g., PCB) or another device (e.g., another die) by way of any suitable electrical connector, such as wire bonds, to traces 342. For example, the traces 342 may be electrically coupled to an external device such that the traces 342 can receive input signals for the electrical connections 330 and transmit output signals to the external device. In some embodiments, control signals and/or electrical current can be sent, for example, from an external device, to electrical connections 330 and then conveyed through the thermal platform 332 and/or integrated circuit 304, through the interconnects 320 and into the control circuit 309 of the heating element 306.

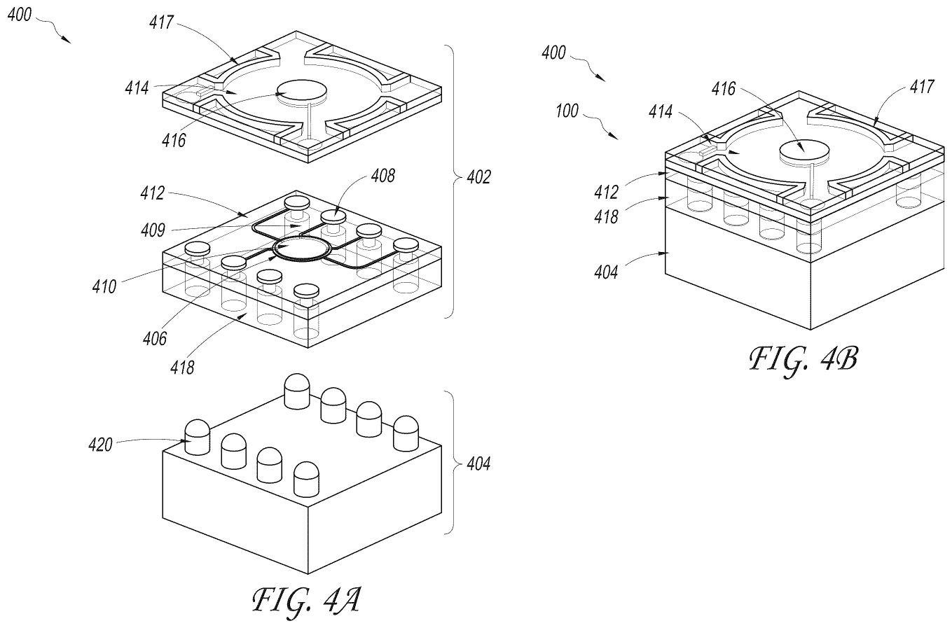

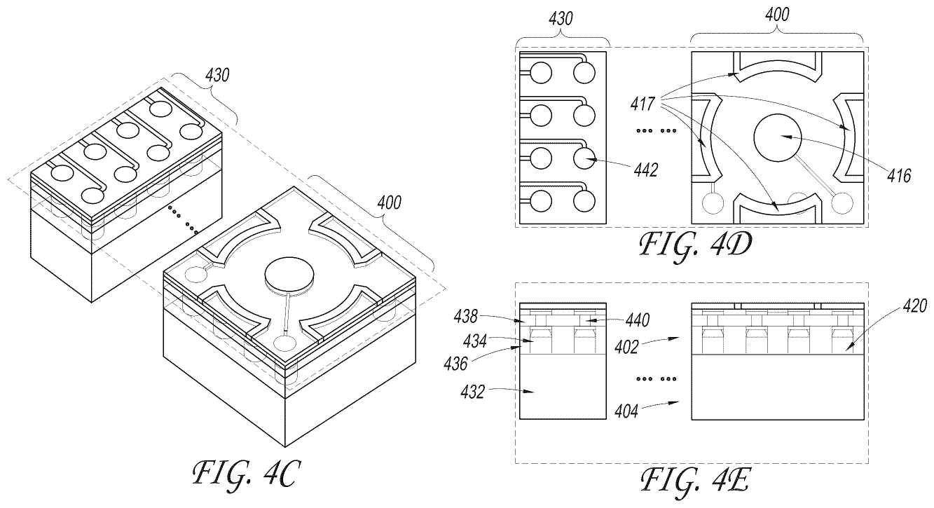

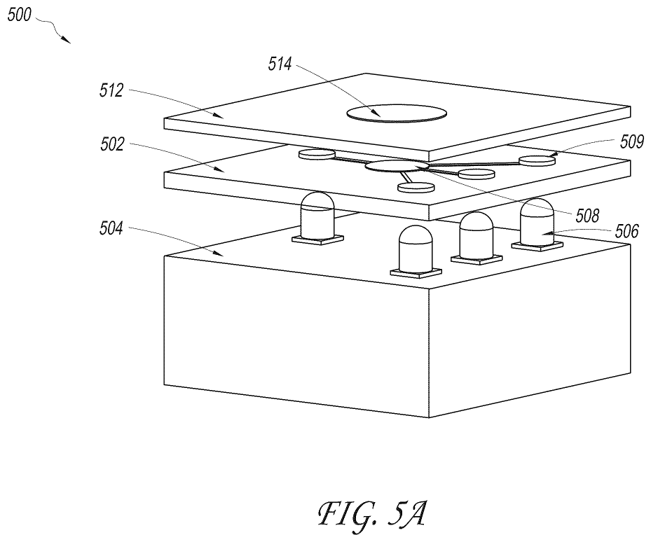

FIGS. 4A-4E show another embodiment of a sensor assembly 400 according to this disclosure. FIG. 4A is an exploded view of the sensor assembly 400. FIG. 4B shows the assembled sensor assembly 400 and FIGS. 4C-4E schematically show the assembled sensor assembly 400 in an electronic assembly with electrical connections 430 that can provide input/output connections for the sensor assembly 400. The sensor assembly 400 can similarly include an integrated circuit 404 (e.g., CMOS ASIC) and a flexible circuit 402 (e.g., flex). In some embodiments, the integrated circuit 404 can include a plurality of interconnects 420 (e.g., copper pillars). The flexible circuit 402 can similarly include a fluidic interposer 412 and a plurality of electrical connections 408 connected to the interconnects 420 on the integrated circuit 404. In some embodiments, the flexible circuit 402 can also include a bottom side resist 418 configured to receive the interconnects 420, allowing stable connection between the electrical connections 408 on the fluidic interposer 412 and the interconnects 420 on the integrated circuit 404. In some embodiments, the fluidic interposer 412 can include a heating element 406 with one or more of the electrical connections 408 providing power to the heating element 406.

As described in more details above, with respect to FIGS. 3A-3E, a passivation layer 410 can be disposed on top of the heating element 406 to coat at least a top side of the heating element 406 and thereby electrically passivate the local area. A reaction pad 416 can be sputtered on the passivation layer 410. In some embodiments, the flexible circuit 402 can further include a photoresist layer 414 (e.g., biocompatible resist layer). The reaction pad 416 may be embedded in the photoresist layer 414 with top and bottom sides exposed. In some embodiments, the reaction pad 416 and the rest of the sensor assembly 400 can be thermally connected to the heating element 406 and electrically isolated by the passivation layer 410. The thickness of the reaction pad 416 can be further defined by electroplating process. In some embodiments, the photoresist layer 414 can further define the surface properties, geometric patterns, and other mechanical or biochemical properties of the sensor assembly 400. The reaction pad 416 can be embedded in the photoresist layer 414 with top and bottom sides exposed.

As described in more details above, with respect to FIGS. 3A-3E heat can flow both ways between the reaction pad 416 and the heating element 406. In some embodiments, heat can flow between the reaction pad 416 and the heating element 406 through at least the electrical passivation layer 410. The heating element 406 can include a control circuit 409 to convert the heat flow from the reaction pad 416 to one or more electrical signals (e.g., temperature signals). In some embodiments, signals can be sent through the interconnects 420 to the heating element 406 to generate heat which is transferred upward to the reaction pad 416. In such embodiment, heat intentionally does not flow down through the interconnects 420. In some embodiments, electrical signals from the control circuit 409 in the heating element 406 can be transmitted down to the integrated circuit 404 through the one or more electrical connections 408 on the fluidic interposer 412 and the interconnects 420.

As shown in FIG. 4A, the flexible circuit 402 can further include one or more additional reaction electrodes 417 embedded in the photoresist layer 414, for example, four electrodes 417. In certain embodiments, electrodes 417 have an approximate “M” shape, as illustrated in FIGS. 4A-4E, with a set of electrical leads positioned on the edge of the flexible circuit 402. In some embodiments, each of the electrodes 417 may be positioned along an edge of the flexible circuit 402 such that another sensor assembly 400 according to this disclosure may be positioned next to the current one and be electrically connected through the set of electrical leads on the electrodes 417, as described above with respect to FIGS. 2A-2E. In some embodiments, the electrodes 417 can be electrically connected to the integrated circuit 404 through the electric connections on the fluidic interposer 412 and the interconnects 420 on the integrated device to allow transmission of electrical and/or informational signals.

In some embodiments, the sensor assembly 400 can be connected to a set of electrical connections 430 through the integrated circuit 404 as shown in FIGS. 4C-4E. The electrical connections 430 can similarly include a thermal platform 432 having an integrated circuit, for example, a complementary metal-oxide-semiconductor application-specific integrated circuit (“CMOS ASIC”). In some embodiments, thermal platform 432 of the electrical connections 430 and integrated circuit 404 of the sensor assembly 400 can be connected or form a single body. In some embodiments, the electrical connections 430 can further include interconnects 434 (e.g., copper pillars) embedded in an underfill 436 on top of the thermal platform 432. In some embodiments, the electrical connections 430 can further include a flexible circuit 438 with vias 440 and traces 442 on top of the interconnects 434.

In some embodiments, the electrical connections 430 can further be connected to an external device, such as a package substrate (e.g., PCB) or another device (e.g., another die) by way of any suitable electrical connector, such as wire bonds, to the traces 442. For example, the traces 442 may be electrically coupled to an external device such that the traces 442 can receive input signals for the electrical connections 430 and transmit output signals to the external device.

In some embodiments, control signals and/or electrical current can be sent, for example, from an external device, to electrical connections 430 and then conveyed through the thermal platform 432 and/or integrated circuit 404, through the interconnects 420 and into the control circuit 409 of the heating element 406. As described in more detail in FIGS. 2A-2E, control signals and/or electrical current may also be transmitted to adjacent sensor assemblies 400 from an external device via a connection path through the thermal platform 432 and/or integrated circuit 404, interconnects 420, and electrodes 417. Similarly, control signals and/or electrical currents may be provided to the control circuit 409 of heating element 406 from an adjacent sensor assembly 400, rather than the external device, via a connection path through the electrodes 417, interconnects 420, and integrated circuit 404.

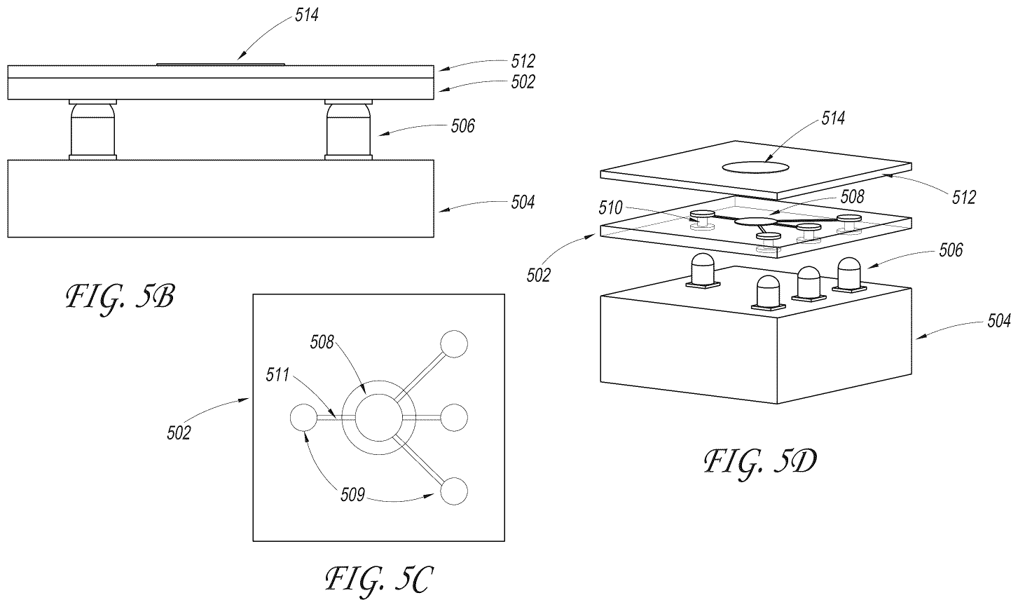

FIGS. 5A-5D show another embodiment of a sensor assembly 500 according to this disclosure. FIG. 5A is an exploded view of sensor assembly 500. FIG. 5B illustrates a cross section of the sensor assembly 500. FIG. 5C illustrates a top view of the sensor assembly 500 with a transparent thermal layer 512. FIG. 5D illustrates an exploded view of the sensor assembly 500 with a transparent interposer 502, such that vias 510 are visible.

As shown in FIGS. 5A-5D, the sensor assembly 500 can include an interposer 502 and an integrated circuit die 504 configured to electrically connect to the interposer 502. In some embodiments, the integrated circuit die 504 can comprise one or more converters and/or one or more amplifiers. In some embodiments, the interposer 502 and the integrated circuit die 504 can be electrically connected through one or more interconnects 506. The one or more interconnects 506 can include copper pillars or other suitable conductive or semiconductive material.

In some embodiments, the interposer 502 can be a substrate. In some embodiments, the interposer 502 can be a flexible substrate, for example an insulating material (e.g., a polymer such as polyimide) with embedded conductive traces 511 and pads 509. In some embodiments, the interposer 502 can be made of a dielectric material. The interposer 502 can include a heater 508 embedded in the interposer 502. The heater 508 can be configured to generate thermal energy when electrical current is supplied. The heater 508 can comprise a resistive heater in various embodiments. In some embodiments, the heater 508 can have a serpentine pattern. In some embodiments, the heater 508 can have a resistance in a range of 50 ohm to 250 ohm, or in a range of 80 ohm to 120 ohm, e.g., about 100 ohm. The interposer 502 can also include one or more vias 510 to allow electrical and/or thermal connection between two opposite sides of the interposer 502.

The sensor assembly 500 can further include a thermal layer 512 disposed on the interposer 502. The sensor assembly 500 can further include a sensor 514 (e.g. a metal pad) disposed on the thermal layer 512. The sensor 514 can be configured to be in contact with sample fluids and sense or measure properties of the sample fluids (e.g., temperatures, material properties, etc.). In some embodiments, the sensor 514 can comprise a functionalized electrode with a functionalizing material disposed on the pad. In some embodiments, the sensor 514 can be configured to be thermally coupled with and electrically isolated from the heater 508 of the interposer 502. In some embodiments, the sensor 514 can be configured to be electrically isolated from the heater 508 of the interposer 502. In some embodiments, the sensor 514 can be configured to be thermally coupled with and electrically isolated from the interposer 502. In some embodiments, the sensor 514 comprises a gold pad.

In some embodiments, the thermal layer 512 can be made of a material with properties that are electrically and thermally insulating. However, the thickness of the thermal layer 512 can be provided to be sufficiently thin so as to conduct heat between the sensor 514 and the heater 508 or vias 510. Heat generated by the heater 508 can be configured to heat at least a portion of the sample fluids to desired temperatures or for a desirable amount of time. In some embodiments, the heat can reach the portion of the sample fluids by passing through the thermal layer 512.

The thermal layer 512 can have a composition and a thickness that electrically isolates or separates the sensor 514 (e.g., pad) from the heating element and vias 510 of the interposer 502. In various embodiments, the thermal layer 512 can comprise a thermally and electrically insulating material that is nevertheless dimensioned to be thin enough to conduct heat vertically between the sensor 514 and the underlying vias 510 and heater 508 of the interposer 502. In various embodiments, the thermal layer 512 can comprise a polymer (such as polyimide) provided on the interposer 502 by way of an adhesive. In other embodiments, an inorganic dielectric layer (such as silicon nitride) can be provided over the interposer 502.

In various embodiments, when the sensor assembly 500 is in use, the heater 508 can be turned on to heat the sensor assembly 500 and/or at least a portion of fluids around the sensor 514 to desired temperatures. In some embodiments, the heater 508 can be turned on by supplying a current to the heater 508, e.g., through the interconnects 506, vias 510, and traces 511 of the interposer 502. The heater 508 can then be turned off to allow the sensor 514 to sense or measure information about the fluids (e.g., temperatures, etc.). For example, heat can flow from the fluid sample to the pad, through the thermal layer 512 to the vias 510 of the interposer 502, and to the integrated circuit die 504 by way of the interconnects 506. Sensed information (e.g., temperatures or changes in temperature) can be processed by the integrated circuit die 504. In some embodiments, the sensed information from the sensor 514 can be transmitted to the integrated circuit die 504 through vias 510, interconnects 506, contact pads 509, and/or solder bumps. The integrated circuit die 504 can then transmit sensed information, processed or unprocessed, through a connector to external devices.

For example, when the sensor assembly 500 shown in FIGS. 5A-5D is in use, the integrated circuit die 504 can be configured to transmit a current to the heating element by way of the interconnects 506 and vias 510 (and traces 511 and/or pads 509 connected to the vias 510) to generate heat at the heating element. The heating element can pass the heat through the thermal layer 512 and the heater 508 to at least a portion of the sample fluids around the heater 508. The generated heat can heat the portion of sample fluids such that the portion of sample fluids chemically, mechanically, or biologically reacts to achieve a desirable sensing condition. The integrated circuit die 504 can then be configured to turn off the current to the heater 508 and stop generating heat at the heater 508. When the heater 508 stops providing heat, the sensor 514 can be configured to transduce and transfer temperature information (e.g. a change in temperature) to the integrated circuit die 504 through the interposer 502 and the interconnects 506.

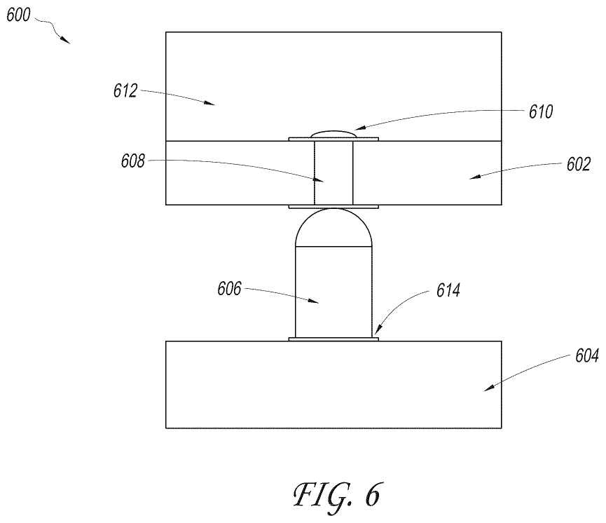

FIG. 6 shows another embodiment of a sensor assembly 600 according to this disclosure. The sensor assembly 600 can similarly include an interposer 602 and an integrated circuit die 604 electrically connected to the interposer 602. The interposer 602 and the integrated circuit die 604 can be electrically connected by interconnects 606 (e.g., copper pillars). In some embodiments, the interposer 602 can include one or more vias 608 to electrically connect two opposite sides of the interposer 602. The sensor assembly 600 can further include a sensor 610 configured to be in contact with sample fluids 612 and sense or measure information about the sample fluids 612 (e.g., temperatures, voltages, etc.).

The sensor assembly 600 can further include a heater 614 disposed in or on the integrated circuit die. The heater 614 can be configured to generate heat when a current is supplied. In some embodiments, the heater 614 can be disposed between one or more interconnects 606 and the integrated circuit die. In some embodiments, the heater 614 can be configured to heat at least a portion of sample fluids 612 by generating heat that passes through the interconnects 606, the interposer 602, and the sensor 610.

The sensor assembly 600 shown in FIG. 6 can work similarly as described above to sense and transduce information with the sensor 610 and transmit that information to the integrated circuit die 604 for processing. For example, when the sensor assembly 600 shown in FIG. 6 is in use, the integrated circuit die 604 can be configured to turn on the heater 614. The generated heat can pass through the one or more interconnects 606 and the interposer 602 to the sensor 610 and at least a portion of the sample fluids 612 around the sensor 610. The generated heat can heat the portion of sample fluids 612 such that the portion of sample fluids 612 chemically, mechanically, or biologically reacts to achieve a desirable sensing condition. The heater 614 can then be turned off and stop generating heat. When heat is no longer provided to the sensor 610, the sensor 610 can transduce and transfer temperature information (e.g. a change in temperature) to the integrated circuit die 604 through the interposer 602 and the interconnects 606.

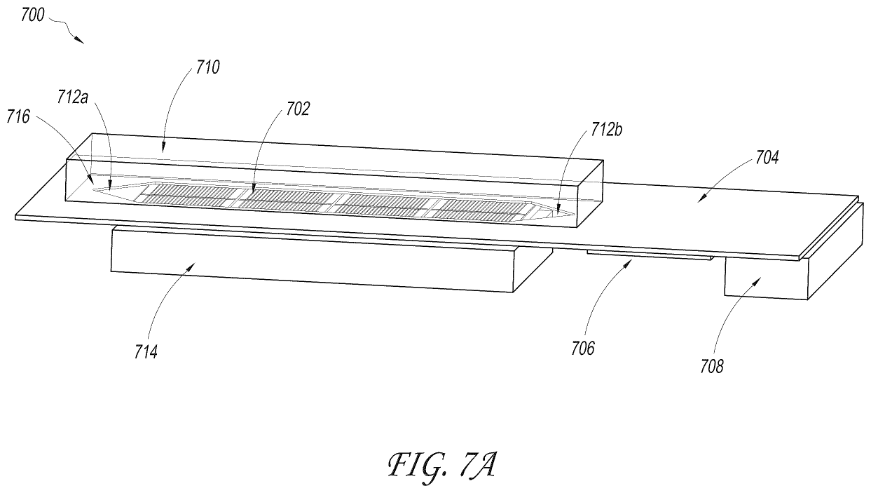

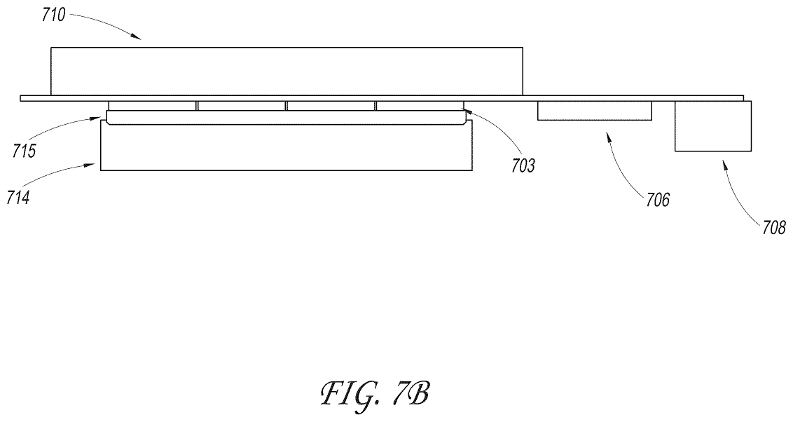

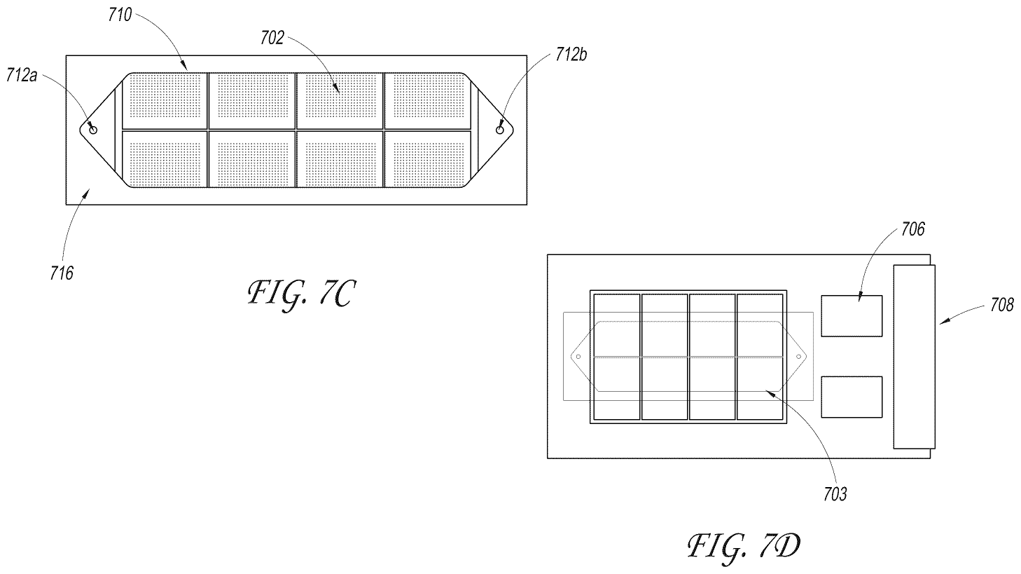

FIGS. 7A-7D illustrate an embodiment of a fluidic sensor package 700 that utilizes a plurality of sensor assemblies 702. FIG. 7A illustrates a perspective view of the fluidic sensor package 700, FIG. 7B illustrates a cross section of the fluidic sensor package 700, FIG. 7C is a top view of a flow cell 710 on the fluidic sensor package 700, and FIG. 7D is a bottom view of the fluidic sensor package 700. The plurality of sensor assemblies 702 may correspond to any of the embodiments of a sensor assembly as described herein, such as sensor assembly 100, sensor assembly 200, sensor assembly 300, sensor assembly 400, sensor assembly 500, or sensor assembly 600 described above.

As shown in FIGS. 7A-7D, the plurality of sensor assemblies 702 can be coupled to one another and implemented in the fluidic sensor package 700. The fluidic sensor package 700 can include any desirable number of sensor assemblies 702 to achieve desirable results. In some embodiments, the fluidic sensor package 700 can have eight sensor chips 703, each sensor chip having 384 sensor assemblies 702.

The fluidic sensor package 700 can further include a stiffener 704 configured to provide a rigid structure to the fluidic sensor package 700. Various electrical components 706 can be coupled to the stiffener 704 as needed. In some embodiments, a connector 708 can be coupled to the stiffener 704 and configured to transmit signals from the sensor assemblies 702 to external devices. The fluidic sensor package 700 can further include a flow cell 710 mounted to the stiffener 704. In some embodiments, the flow cell 710 can be mounted to a first side of the stiffener 704. The flow cell 710 can include fluid entry hole 712a and fluid exit hole 712b configured to allow one or more sample fluids to enter, flow through, and/or be maintained in the flow cell 710. In some embodiments, the stiffener 704 can include a gasket 716 configured to seal the flow cell 710 such that fluid can only pass through the fluid entry hole 712a and fluid exit hole 712b.

A plurality of sensor assemblies 702 disclosed herein can be coupled to the stiffener 704 such that the sensors of the sensor chips 703 are exposed. Individual sensor assemblies 702 of the plurality thereof may include a fluidic interposer configured to separate a fluid inside the flow cell 710 and an integrated circuit or chip below the fluidic interposer. In some embodiments, the fluidic interposer can be a substrate. In some embodiments, the interposer can be a flexible substrate (e.g., polymide).

In some embodiments, the plurality of sensor chips 703 can be coupled to a second side of the stiffener 704, opposite to the first side. The stiffener 704 can include an opening to allow the sensors of the sensor chips 703 to be exposed to contents of the flow cell 710. In some embodiments, the plurality of sensor chips 703 can be coupled to the stiffener 704 at a first side of the sensor chip. The fluidic sensor package 700 can further include a cooling block 714 coupled to a second side of the plurality of sensor chips 703, opposite to the first side of the plurality of sensor chips 703. The cooling block 714 can be coupled to the plurality of sensor chips 703 through a thermal interface material 715 (e.g., thermal conductive adhesive). The cooling block 714 can be configured to provide a cooling effect to the fluidic sensor package 700.

Reference throughout this specification to “some embodiments” or “an embodiment” means that a particular feature, structure, element, act, or characteristic described in connection with the embodiment is included in at least one embodiment. Thus, appearances of the phrases “in some embodiments” or “in an embodiment” in various places throughout this specification are not necessarily all referring to the same embodiment and may refer to one or more of the same or different embodiments. Furthermore, the particular features, structures, elements, acts, or characteristics may be combined in any suitable manner (including differently than shown or described) in other embodiments. Further, in various embodiments, features, structures, elements, acts, or characteristics can be combined, merged, rearranged, reordered, or left out altogether. Thus, no single feature, structure, element, act, or characteristic or group of features, structures, elements, acts, or characteristics is necessary or required for each embodiment. All possible combinations and subcombinations are intended to fall within the scope of this disclosure.

As used in this application, the terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

Similarly, it should be appreciated that in the above description of embodiments, various features are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that any claim require more features than are expressly recited in that claim. Rather, inventive aspects lie in a combination of fewer than all features of any single foregoing disclosed embodiment.

The foregoing description sets forth various example embodiments and other illustrative, but non-limiting, embodiments of the inventions disclosed herein. The description provides details regarding combinations, modes, and uses of the disclosed inventions. Other variations, combinations, modifications, equivalents, modes, uses, implementations, and/or applications of the disclosed features and aspects of the embodiments are also within the scope of this disclosure, including those that become apparent to those of skill in the art upon reading this specification. Additionally, certain objects and advantages of the inventions are described herein. It is to be understood that not necessarily all such objects or advantages may be achieved in any particular embodiment. Thus, for example, those skilled in the art will recognize that the inventions may be embodied or carried out in a manner that achieves or optimizes one advantage or group of advantages as taught herein without necessarily achieving other objects or advantages as may be taught or suggested herein. Also, in any method or process disclosed herein, the acts or operations making up the method or process may be performed in any suitable sequence and are not necessarily limited to any particular disclosed sequence.

What is claimed is:

1. A sensor assembly comprising:
an integrated circuit die;
an interconnect connected to the integrated circuit die;
an interposer mounted over and connected to the interconnect;
a heating element disposed in or on the interposer; and
a sensor configured to transduce a property of one or more sample fluids,
a thermal pathway between the sensor and the heating element.

2. The sensor assembly of claim 1, further comprising a resist layer mounted to the interposer, wherein the sensor is disposed on the resist layer.

3. The sensor assembly of claim 1, further comprising an electrical passivation layer disposed on at least the heating element to electrically passivate a local area.

4. A sensor assembly comprising:
an integrated circuit;
one or more interconnects coupled to the integrated circuit; and
a substrate mounted over and connected to the one or more interconnects, the substrate comprising:
an interposer;
a heating element disposed on the interposer;
a photoresist layer mounted over and connected to the interposer; and
a reaction pad disposed on the interposer above the heating element, the reaction pad configured to transduce a property of one or more sample fluids;
wherein the heating element is configured to heat the one or more sample fluids.

5. The sensor assembly of claim 4, further comprising an electrical passivation layer disposed on the heating element, wherein the electrical passivation layer electrically isolates the reaction pad and the heating element.

6. The sensor assembly of claim 5, wherein the photoresist layer and the electrical passivation layer are thermally conductive, and wherein the electrical passivation layer comprises at least one of a polyimide or silicon nitride.

7. The sensor assembly of claim 5, wherein the photoresist layer and electrical passivation layer form a thermal pathway between the reaction pad and the heating element.

8. The sensor assembly of claim 4, wherein the integrated circuit comprises one or more amplifiers and one or more converters.

9. The sensor assembly of claim 4, wherein the substrate is comprised of flexible material.

10. The sensor assembly of claim 4, wherein the substrate further comprises:
a plurality of electrodes disposed in the photoresist layer and electrically connected to a plurality of electrical connections disposed on the interposer over a plurality of vias through the interposer; and
wherein the plurality of electrodes are electrically coupled to at least one interconnect of the one or more interconnects via the plurality of electrical connections, and wherein each of the plurality of electrodes are configured to transmit electrical signals received from the integrated circuit through the at least one interconnect.

11. The sensor assembly of claim 4, wherein the substrate further comprises an underfill layer coupled on one side of the interposer in contact with the integrated circuit, the underfill layer configured to receive the one or more interconnects.

12. The sensor assembly of claim 4, wherein the substrate further comprises one or more heater control circuits disposed in or on the integrated circuit, the one or more heater control circuits configured to provide power to the heating element and to convert heat flow from the reaction pad into one or more electrical signals.

13. The sensor assembly of claim 4, wherein the reaction pad is exposed to a fluid pathway through which the one or more sample fluids is to be delivered.

14. A fluidic sensor package comprising:
a plurality of sensor assemblies, each sensor assembly of the plurality of sensor assemblies comprising:
an integrated circuit;
one or more interconnects coupled to the integrated circuit; and
a substrate mounted over and connected to the one or more interconnects, the substrate comprising:
a heating element configured to heat one or more sample fluids;
a photoresist layer mounted over the heating element; and
a reaction pad disposed on the photoresist layer above the heating element, the reaction pad configured to transduce a property of the one or more sample fluids; and
a flow cell coupled to the plurality of sensor assemblies and forming a fluid pathway for the one or more sample fluids on a first side of the plurality of sensor assemblies.

15. The fluidic sensor package of claim 14, further comprising a stiffener to provide support to the plurality of sensor assemblies.

16. The fluidic sensor package of claim 14, further comprising a cooling block coupled to a second side of the plurality of sensor assemblies, opposite to the first side of the plurality of sensor assemblies, the cooling block configured to disperse heat from the plurality of sensor assemblies.

17. The fluidic sensor package of claim 16, wherein the cooling block is coupled to the plurality of sensor assemblies through a thermally conductive adhesive.

18. The fluidic sensor package of claim 14, further comprising a connector configured to electrically connect the plurality of sensor assemblies to one or more external devices.

19. The fluidic sensor package of claim 14, wherein each sensor assembly of the plurality of sensor assemblies further comprises:
a plurality of electrodes disposed in the photoresist layer and electrically connected to a plurality of electrical connections; and
wherein the plurality of electrodes are electrically coupled to at least one interconnect of the one or more interconnects via the plurality of electrical connections;
wherein each of the plurality of electrodes are configured to transmit electrical signals received from the integrated circuit through the at least one interconnect; and
wherein at least a portion of the plurality of electrodes are electrically coupled to at least a portion of the plurality of electrodes of another sensor assembly of the plurality of sensor assemblies and transmit electrical signals received from the integrated circuit through the at least one interconnect.

20. The fluidic sensor package of claim 14, further comprising a connector configured to electrically connect the plurality of sensor assemblies to one or more external devices.
